(19) United States
(12) Patent Application Publication
(10) Pub. No.: US 2002/0190733 A1
(43) Pub. Date: Dec. 19, 2002

(54) Circuit for detecting a minute change in resistance

(76) Inventors: Dainichiro Kinoshita, Minami-ku (JP); Takeshi Aoyama, Minami-ku (JP)

Correspondence Address: PRICE AND GESS, Ste. 250, 2100 S.E. Main St., Irvine, CA, 92614, US

(21) Appl. No.: 10/166,431

(22) Filed: Jun. 10, 2002

(30) Foreign Application Priority Data
Jun. 11, 2001 (JP) 2001-175572
Nov. 16, 2001 (JP) 2001-351416

(51) Int. Cl. G01R 27/08

(52) U.S. Cl. 324/713

(57) ABSTRACT

A circuit for detecting a minute change in resistance of the present invention includes: two resistance sensors which have the same electric properties and are connected in series, and an amplifying circuit which adds the voltage generated between the connection point of these resistance sensors and one end thereof to the voltage generated between the connection point and the other end thereof for amplification. A current supply unit feeds a predetermined constant current to the two resistance sensors in a state of being electrically isolated from the amplifying circuit whereby accurate measurements can be made at a relatively low cost over an extended period of time.

### BACKGROUND OF THE INVENTION

1. Field of the Invention

The present invention relates to a circuit for detecting a minute change in resistance in a resistance sensor where a change in resistance value is formed into a detecting signal, such as a minute flow sensor used in an analyzer with light occurring intermittently, such as typified by an infrared analyzer, a circuit for detecting a minute change in resistance in a resistance sensor that must have long-term stability, such as a mass flow meter of a mass flow controller, and further to a circuit for detecting a minute change in resistance with improved detecting performance.

2. Description of the Prior Art

FIGS. 8 and 9 show a general structure of a circuit for detecting a minute change in resistance used in an infrared gas analyzer. FIG. 8 is a schematic view showing the entire structure of an infrared gas analyzer 40 using a conventional circuit for detecting a minute change in resistance, which is a so-called single beam (single cell) type.

As shown in FIG. 8 the infrared gas analyzer 40 is composed of a cylindrical measuring cell 41 whose ends are sealed with cell windows 42, 43 made from a material transmissive of infrared, an inlet 44 and an outlet 45 for a sample gas S, an infrared light source 46 provided to face the cell window 42 so as to emit infrared rays IR to be turned into intermittent light of a predetermined frequency by a light chopper 47 disposed between the infrared light source 46 and the cell window 42.

The analyzer 40 further includes a detector 48 provided to face the cell window 43. The detector 48 has a main block 49 made from a corrosion-resistant metal and its ends are sealed with windows 50, 51 made from a material transmissive of infrared rays, and its inside is divided into two gas chambers 53, 54 separated by a window 52 made from a material tansmissive of infrared rays. These gas chambers 53, 54 are arranged to be serial along an infrared light path (indicated with arrow IR) with regard to the measuring cell 41. The window 51 is not necessarily an IR penetrating window, and can be made as a sealing member from the same material as the main block 49.

The gas chambers 53, 54 are filled with a gas G showing the same absorbing properties as a gas to be measured (or the gas G can be the gas to be measured). The gas chambers 53, 54 are connected with each other by a gas passage 55, and the gas passage 55 has openings 55a, 55b leading to the gas chambers 53, 54, respectively. The gas passage 55 has an enlarged space 55c where a pair of resistance sensors 56 is provided as a flow sensor for detecting the amount of the gas G that is passing through the gas passage 55 and a voltage is applied to the sensors 56.

Thus, the pair resistance sensors 56 are composed of resistance sensors 56a, 56b. One end of each sensor is connected with each other, the other end is connected in series to each of bias resistances 57a, 57b, and the other end of each of the bias resistances 57a, 57b is connected with each other to form a bridge circuit 58 shown in FIG. 9. The connection point of one end side of the pair resistance sensors 56 (the side at which the resistance sensors 56a, 56b are connected) is grounded to a common potential.

A bridge power supply 59 applies a bridge voltage on the bridge circuit 58. In other words, a bridge voltage is applied on the bridge circuit 58 including the pair resistance sensors 56 so as to make the bridge circuit 58 a measuring circuit. A subtraction circuit 60 detects the difference in voltage at the other end side between the pair resistance sensors 56a, 56b and obtains an output signal 0 from the bridge circuit 58.

In the following description about the basic operations of the detector 48 thus structured, assume that the gas chambers 54, 55 are filled with the same gas (CO₂, for example) as the gas to be measured. When the measuring cell 41 is radiated with infrared rays IR from the infrared light source 46 while the sample gas S containing CO₂ is supplied to the measuring cell 41, the infrared rays IR, which are absorbed in the CO₂ in the sample gas S, go into the gas chamber 53 on the measuring cell 2 side in the detector 48. The gas G (CO₂ in this case) sealed inside the gas chamber 53 absorbs part of the infrared rays IR and increases its temperature to expand. The expanded gas G goes into the gas passage 55 from the opening 55a, passes through the space 55c and flows into the gas chamber 54 from the opening 55b.

At this moment, heat is taken from the upstream resistance sensor 56a of the pair resistance sensors 56 in accordance with the rate (amount) of the gas G flowing inside the gas passage 55. As a result, the resistance sensor 56a is cooled according to the flow rate of the gas G to make its temperature lower than in a state of no flow. On the other hand, the gas G is heated by the released heat and in turn warms the downstream resistance sensor 56b. Since the electric resistance value of the resistance sensor 56a changes at a fixed rate according to a temperature change, this change in the resistance value causes a difference in voltage at the other end side between the pair of resistance sensors 56a, 56b, thereby outputting the output signal 0.

As described above, the gas G expands to different degrees between the gas chambers 53 and 54 of the detector 48, and when the gas G flows inside the gas passage 55, the amount of flow is measured. The measured value has a fixed relation with the concentration of the component to be measured (CO₂ in this case) contained in the sample gas S supplied to the measuring cell 41 of the infrared gas analyzer 1, so that the concentration of the component to be measured can be measured.

In the circuit shown in FIG. 9 when the bridge power supply 59 has a voltage of E[V]; the resistance sensors 56a, 56b have resistance values Rsa, Rsb[Ω], respectively, and the bias resistances 57a, 57b have a resistance value of Rb[Ω], the detecting signal Δe[V] to be entered to the calculation circuit 60 in this circuit 58 is shown in formula (1) below.

$$Δ e = \frac{R s a \times E}{R b + R s a} - \frac{R s b \times E}{R b + R s b} \qquad ( 1 )$$

The resistance values Rsa, Rsb of the sensor resistances 56a, 56b slightly change when the sensor resistances 56a, 56b decrease their temperatures due to the minute flow of air caused be the difference in pressure resulting from the absorption of infrared rays inside the detector. The changes in the resistance values Rsa, Rsb are detected, amplified, and outputted as the measured values. The changes in the resistance values Rsa, Rsb are outputted in the form of changes in alternating voltage difference Δe by the intermittence of the infrared rays IR.

However, according to the above-described measuring method, the resistance 56 to be measured is connected in serial with the bias resistance 57, and a predetermined voltage is applied to the synthesized resistance so as to measure the voltage divided by the resistance 56. Thus this method is far from the principle of measuring resistance, thereby causing various problems.

For example, as known from the formula (1), in order to obtain the stability of the voltage difference Δe or the output signal 0 and sufficient sensibility resulting from changes in the resistance values Rs (Rsa, Rsb), it is necessary to secure a stable supply of the resistance values Rs, Rb and the voltage E of the voltage supply 59 from and the power supply 59. However, the voltage supplied from the voltage supply 59 to the bridge 58 inevitably suffers from a voltage drop not only by the internal resistance on the power supply side but also a resistance Re which may cause an error such as wire resistance or contact resistance existing on the wire, which is a cause of error in measurement.

The resistance sensor 56 must be provided with a predetermined amount of electric power W₀ shown in the following formula (2) to be heated and to increase in temperature. Therefore, when the power to be supplied to the resistance sensor 56 is adjusted, the resistance value Rb of the bias resistance 57 must be also adjusted, making it difficult to determine each constant uniquely.

$${W}_{0} = \frac{R s \times {E}^{2}}{{( R b + R s )}^{2}} \qquad ( 2 )$$

In other words, the formula (2) indicates that it is necessary to reduce the resistance value Rb of the bias resistance 57 in order to supply more electric power to the resistance sensor 56, and the formula (1) indicates that the resistance value Rb of the bias resistance 57 must be increased to some degree in order to obtain a stable output. Since these are mutually contradictory, the resistance value Rb of the bias resistance 57 in the prior art must be considered from both aspects of the improvement in the sensitivity of detection and the amount of power to be supplied to the resistance sensor 56. This makes it difficult to cope with changes in specification (resistance value, amount of heat, or the like) of the resistance sensor 56.

In the above-described conventional method, the bias resistance 57 is positioned on the circuit connected from the power supply 59 to the resistance sensor 56, so that the bias resistance 57 must be fed some current for the resistance sensor 56 to produce heat, which causes the performance of the bias resistance 57 to greatly affect the detecting performance. In other words, the bias resistance 57 must be a highly precise and highly stable resistance having a fixed resistance value, regardless of temperature change due to its own heat generation, thereby making the resistance 57 expensive. There is the additional problem that since the bias resistance 57 also consumes electric power, more energy is wasted.

Furthermore, when there is a voltage drop due to wire resistance or the like between the power supply 59 and the bridge circuit, a change in one of the resistance values Rsa, Rsb of the resistance sensors 56a, 56b may affect the current flowing in the other of the resistance sensors 56b, 56a, which might have a detrimental effect on the measured results.

Since the measured results are expressed in the difference between divided voltage values of the resistance sensors 56a, 56b, the calculation circuit 60 must have a circuit for performing comparatively complicated subtraction as its calculation amplifier. In this subtraction circuit 60, both input terminals of the calculation amplifier are connected to the measuring points far from the grounding point so that they are vulnerable to external disorder, therefore, it becomes necessary to use a special amplifier for calculation.

The following is a description of the case where two resistance sensors connected in series are used in a mass flow meter, and the amount of flow is measured by minute changes in the resistance values. FIG. 10 is a cross sectional view showing an example of a so-called mass flow meter.

The general mass flow meter 61 shown in FIG. 10 includes a main body 62 which composes a main flow passage 62a flowing the gas to be measured; a tube 63 which composes a branch passage 63a; resistance sensors Rs₁, Rs₂ composed of two heating wires coiled at two adjacent sites on the tube 63; a circuit 64 for detecting minute change in resistance which includes resistance sensors Rs₁, Rs₂ and finds the amount of flow Q from the minute changes in the resistance values; and a cover 65 which covers the tube 63 and the circuit 64 for detecting minute change in resistance so as to keep them away from outer air.

FIG. 11 shows a circuit 64p for detecting minute change in resistance illustrated to explain the circuit 64 for detecting minute change in resistance in FIG. 10. FIG. 11 includes a power supply unit 66 which supplies constant current I to the resistance sensors Rs₁, Rs₂; reference resistances Rb₁, Rb₂, and Rb arranged in parallel to the resistance sensors Rs₁, Rs₂; and an amplifier 67. In other words, the circuit 64p for detecting minute change in resistance composes a bridge circuit, which detects and amplifies minute changes in resistance in the resistance sensors Rs₁, Rs₂ due to the gas flow as the difference in voltage between the reference resistance Rb₁, Rb₂ under the conditions that the current I flows to the resistance sensors Rs₁, Rs₂. Rb is a variable resistance for adjustment.

In general, in order to generate heat, the resistance sensors Rs₁, Rs₂ have lower resistance values than the reference resistances Rb₁, Rb₂, Rb. As a result, most of the current I flows to the resistance sensors Rs₁, Rs₂.

The resistance values of the resistance sensors Rs₁, Rs₂ are basically set to make Rs₁=Rs₂ by adjusting the length and diameter of the heating wires, the coiling density and tension on the tube 63; the reference resistances Rb₁, Rb₂ have resistance values of Rb₁=Rb₂. Therefore, in the case where the synthetic resistance of this bridge is R, the applied voltage E of the bridge is E=I×R, so that the voltage Ea at point α in FIG. 11 becomes Ea=E/2, the voltage Eb at point β becomes Eb=E/2 when the variable resistance Rb is at the midpoint position; and the difference input voltage of the amplifier 67 becomes zero so as to bring the bridge circuit into a condition of equilibrium.

In the circuit 64p for detecting a minute change in resistance, if a fluid in an amount Q flows through the main body 62, this fluid is divided into a ratio Q₁:Q₂ determined by the tube 63 and the like, and the fluid in amount Q₁ flows to the tube 63 so as to change the resistance values of the resistance sensors Rs₁, Rs₂. Changing the resistance values of the resistance sensors Rs₁, Rs₂ unbalances the bridge, making the amplifier 67 output a signal 0 according to the amount Q.

It is extremely difficult to make the resistance sensors Rs₁, Rs₂ have the same resistance values because these resistance values vary depending on the diameter and length of the heating wires, the density to coil around the tube 63, the strength of tension applied when the heating wires are coiled, and the resistance caused in the portions where the resistance sensors Rs₁, Rs₂ are connected with the resistances Rb₁, Rb₂, Rb or with the power supply unit 66. To solve this problem, the equilibrium of the bridge is minutely adjusted by using the variable resistance Rb. After the equilibrium of the bridge is properly compensated, the cover 65 can be applied or the position of the variable resistance Rb is fixed to make the value of the variable resistance Rb unchangeable, thereby keeping the compensated conditions.

However, it is considered that the bridge circuit in the circuit 64p of detecting a minute change in resistance may be unbalanced due to the poor long-term stability of the reference resistances Rb₁, Rb₂ during their production even if the resistance sensors Rs₁, Rs₂ have long-term stability. Above all, in the above-mentioned flow meter, long-term stability is a very important factor because compensation is not generally done again by calibration or the like after shipment. In order to remove these causes of deterioration of long-term stability, it is necessary to use high precision resistances as the reference resistances Rb₁, Rb₂, which leads to a remarkable rise in cost.

In the case where there is a circuit having the function of a compensating bridge equilibrium such as a variable resistance Rb for compensating variations in the resistance sensors Rs₁, Rs₂ during the production as detailed before, it is also important that the element Rb composing this compensating circuit has stability. In other words, since this compensating function becomes a cause of deterioration of the long-term stability of the equilibrium, the element Rb composing the compensating circuit must have high precision to obtain long-term stability, which also leads to an increase in the cost of the circuit 64p for detecting a minute change in resistance.

There is the additional problem that an element for adjustment containing an analog factor such as the variable resistance Rb may change its electric properties when it comes in contact with the element Rb in order to adjust the equilibrium, thereby deteriorating its operability at the time of adjustment. For example, in the case of the variable resistance Rb, there may be variations in resistance value before a driver or the like is applied to the portion to be adjusted for the change of the resistance value and after the driver is removed after adjustment. The adjusting operator has to perform adjustment by taking such variations into consideration.

### SUMMARY OF THE INVENTION

The present invention has been conceived in view of the above-described features, and its first object is to provide a circuit for detecting a minute change in resistance which approaches the detection of a minute change in resistance to the principle of measuring resistance value, thereby offering the same performance with a reduced number of components of high precision and high stability.

A second object of the present invention is to provide a circuit for detecting a minute change in resistance which has improved long-term stability and resultant reliability, improved operability in adjustment, and reduced cost.

In order to achieve the above objects, a circuit for detecting a minute change in resistance of the present invention comprises: two resistance sensors which have the same electric properties and are connected in series; an amplifying circuit which adds the voltage generated between the connection point of these resistance sensors and one end thereof to the voltage generated between the connection point and the other end thereof for amplification; and a current supply which feeds a predetermined constant current to the two resistance sensors in the state of being electrically isolated from the amplifying circuit.

Since the circuit for detecting a minute change in resistance measures the voltages generated at both ends under the conditions that a constant current is supplied to the two resistance sensors, it is an application of the principle of measuring resistance value. Therefore, the resistance values of the resistance sensors can be found with high precision, regardless of the intensity of the contact resistance. In addition, since the resistance values are detected by feeding a constant current only to the resistance sensors, without using conventional bias resistance, not only energy can be saved but also heat evolvement, undesirable for the electric circuit, can be suppressed. There is no need for selecting a high precision bias resistance or designing the resistance value carefully as conventionally done. Thus the circuit can be designed flexibly according to the modifications in specification such as the resistance values and heating value of the resistance sensors.

Since the power supply is insulated from the amplifying circuit, the fixed amount of current flowing to one end of the first resistance sensor from the power supply entirely flows also to the second resistance sensor and goes out from the other end. Consequently, a change in the resistance values of the resistance sensors will not lead to variations in the values of the current flowing to these sensors, thereby securing the detection of changes in the resistance values of the resistance sensors without conventional interference. Since the voltage developed between the connection point of these resistance sensors and one end thereof is opposite to the voltage developed between the connection point and the other end thereof, the difference between the resistance values of these resistance sensors can be easily found by adding both voltages.

In the case where the amplifying circuit is an adding circuit which includes; two resistances having the same electric properties and resistance values and being much larger than the resistance sensors and connected in series between one end and the other end of the resistance sensors; and a calculation amplifier which has a reversal input terminal connected to the connection point of the resistances and which performs negative feedback of the output, there is no need for a special amplifier for instrumentation, and a calculation amplifier which is generally considered to be high precision can be used to compose an adding circuit, thereby reducing the production cost. In addition, the non-reversal input terminal of the calculation amplifier can be grounded together with the connection point of the resistance sensors, thereby further stabilizing the measured value.

In the case where the amplifying circuit is an adding circuit which includes; two amplifiers having an amplitude of 1 arranged respectively at one end and the other end of the resistance sensors; two resistances having the same electric properties and connected in series so as to connect the outputs of both amplifiers; and a calculation amplifier which reversal input terminal is connected to the connection point of the resistances and which performs negative feedback of the output, the current outputted from the current supply is securely provided to both resistance sensors without any diversion, thereby further improving the precision.

In the case where the current supply is a converter which obtains power from the power supply of the amplifying circuit, and outputs a predetermined constant current in the state of being insulated from the power supply of the amplifying circuit, the circuit for detecting a minute change in resistance can have a single, combined power supply. Since an input/output isolation DC-DC converter have come to be mounted comparatively easily in recent years, combining a constant current circuit with this input/output isolation DC-DC converter can form a converter, which outputs a predetermined constant current in the state of being isolated from the power supply of the amplifying circuit.

Another circuit for detecting a minute change in resistance of the present invention comprises: a power supply unit which supplies DC current; two resistance sensors connected in series, both ends thereof being connected with the power supply unit; an intermediate voltage developing circuit, which digitally divides the voltage applied on both ends of the two resistance sensors by switching operations with the use of switch elements; and a detecting unit which detects minute changes in the resistance sensors by comparing the output voltage of the intermediate voltage developing circuit with the voltage at the connection point of the resistance sensors.

Since the intermediate voltage developing circuit digitally divides the voltage applied on both ends of the two resistance sensors by switching operations with the use of switch elements, there is no factor to make the circuit unstable over a long time period. Consequently, a circuit having the bridge function formed by the two resistance sensors and the intermediate voltage developing circuit can keep a stable condition of equilibrium for a long time period. The circuit having the bridge function in the present specification is a bridge circuit in a broad sense as a circuit for detecting changes in resistance value as changes in voltage.

The intermediate voltage developing circuit can be a combination of switch elements and a smoothing circuit or a combination of a filter using an LSI such as DSP (Digital Signal Processor) tailored for high-speed calculation of digital signal processing and an active filter using a calculation amplifier.

In the case where the intermediate voltage developing circuit has a pulse width modulation circuit which perform switching operations, the time at which the switch elements are switched can be adjusted by using an existing pulse width modulation circuit (IC for PWM control, or the like), which facilitates the development of an intermediate voltage of the two resistance sensors.

Another circuit for detecting a minute change in resistance of the present invention comprises: two resistance sensors connected in series and coiled at two adjacent sites on the tube composing the flow passage; a power supply unit which supplies a predetermined DC power to both ends of these resistance sensors; a smoothing circuit which equalizes the entered voltages and outputs them; two switch elements which supply the smoothing circuit with the voltages at both ends of the resistance sensors alternately by a switching operation; a pulse width modulation circuit which supplies switching signals to the switch elements; and a detecting unit which detects minute changes in the resistance sensors by comparing the voltage at the connection point of the resistance sensors with the output voltage of the smoothing circuit.

The smoothing circuit equalizes the voltages supplied by two switch elements to be switched with the use of the signal for switching pulse share determined by the pulse width modulation circuit which supplies both switch elements with switching signals. Consequently, the stability of the analog passive elements composing the smoothing circuit does not seriously affect the voltages to be smoothed and outputted, preventing the bridge circuit from being unbalanced, thereby performing stable division of voltage for a long time period. Thus, the bridge circuit composed of the two resistance sensors, the switch elements, and the smoothing circuit can be kept in a condition of equilibrium for a long time.

In short, the second and third circuits of the present invention for detecting a minute change in resistance are not unbalanced even if calibration is not done for a long time period, thereby improving the reliability. Since it is unnecessary to use expensive passive elements capable of providing stable resistance values for a long time period, the production cost of the device can be reduced.

In the case where the pulse width modulation circuit includes an input unit which receives the set value of pulse width in the form of a digital signal, and a setting switch which outputs to the input unit a set value of pulse width adjusted according to the resistance values of the resistance sensors, the condition of equilibrium can be adjusted digitally through the pulse share of the switching signals to be supplied to the switch elements by manipulating the setting switch. As a result, whether the circuit is in contact with the setting switch or not at the time of setting, there is no influence on the pulse share, thereby improving the operability for adjustment.

In the case where the pulse width modulation circuit includes an input unit which receives the set value of pulse width in the form of a digital signal, and the detecting unit includes a digital signal generation circuit which outputs to the input unit the set value of pulse width to equalize the output voltage of the intermediate voltage developing circuit to the voltage of the connection point of the resistance sensors, the digital signal outputted from the digital signal generation circuit can be outputted as the measured value, thereby facilitating the subsequent digital signal processing.

In the case where the circuit for detecting a minute change in resistance of the present invention further comprises an amplifier disposed between the switch elements and the resistance sensors so as to minimize changes in the current flowing to the resistance sensors, the intermediate voltage developing circuit which divides voltages digitally by a switching operation does not cause fluctuation in the current flowing to the resistance sensors, thereby providing more precise measurement.

Further another circuit for detecting a minute change in resistance of the present invention comprises: a power supply unit which supplies DC power; two resistance sensors connected in series, both ends thereof being connected to the power supply unit; an intermediate voltage developing circuit which digitally divides the voltages applied on both ends of the two resistance sensors through the switching operations with the use of switch elements; and a detecting unit which detects minute changes in the resistance sensors by comparing the output voltage of the intermediate voltage developing circuit with the voltage at the connection point of the resistance sensors, thereby adding the voltage developed between the connection point of the two resistance sensors and one end thereof to the voltage developed between the connection point and the other end thereof.

Further another circuit for detecting a minute change in resistance of the present invention comprises: two resistance sensors connected in series and coiled at two adjacent sites on the tube composing the flow passage; a power supply unit which supplies a predetermined DC power to both ends of these resistance sensors; a smoothing circuit which equalizes the entered voltages and outputs them; two switch elements which supply the smoothing circuit with the voltages at both ends of the resistance sensors alternately by a switching operation; a pulse width modulation circuit which supplies switching signals to the switch elements; and a detecting unit which detects minute changes in the resistance sensors by comparing the voltage at the connection point of the resistance sensors with the output voltage of the smoothing circuit, thereby adding the voltage developed between the connection point of the two resistance sensors and one end thereof to the voltage developed between the connection point and the other end thereof.

### BRIEF DESCRIPTION OF THE DRAWINGS

FIG. 1 is a view showing an example of a detector using a circuit for detecting a minute change in resistance of the present invention;

FIG. 2 is a view showing the circuit structure of the circuit for detecting a minute change in resistance;

FIG. 3 is a view showing a modified example of the circuit for detecting a minute change in resistance;

FIG. 4 is a view showing another example of the circuit for detecting a minute change in resistance of the present invention;

FIG. 5 is a view explaining the operation of each unit of the circuit for detecting a minute change in resistance;

FIG. 6 is a view showing a modified example of the circuit for detecting a minute change in resistance;

FIG. 7 is a view showing another modified example of the circuit for detecting a minute change in resistance;

FIG. 8 is a view showing an example of an infrared gas analyzer using a conventional circuit for detecting a minute change in resistance;

FIG. 9 is a view showing the circuit structure of the conventional circuit for detecting a minute change in resistance;

FIG. 10 is a view showing the structure of a general mass flow meter; and

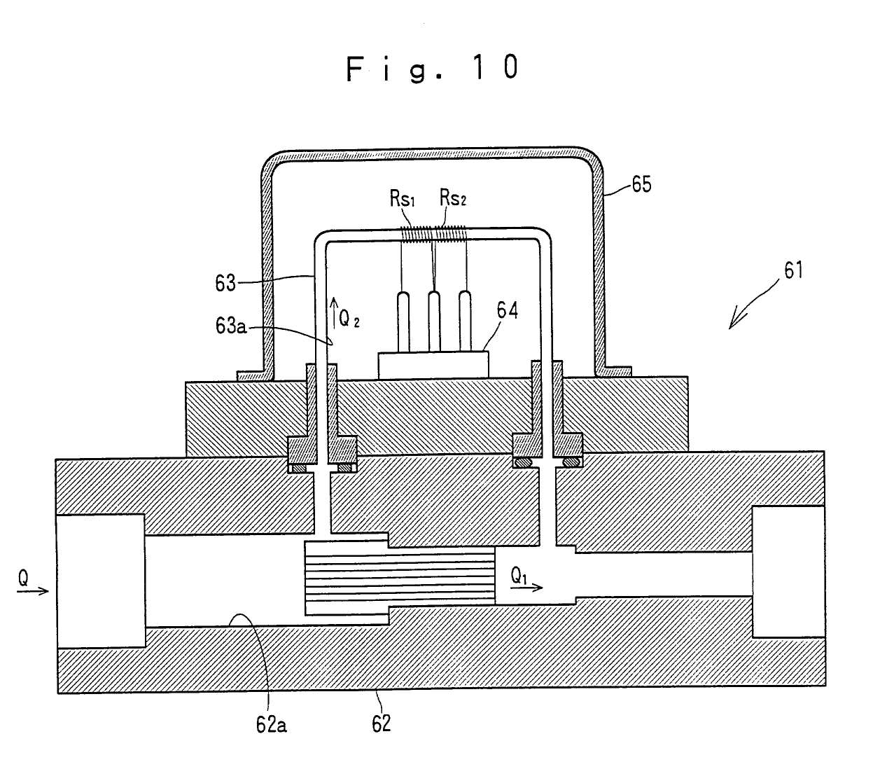

FIG. 11 is a view showing an example of a conventional circuit for detecting a minute change in resistance.

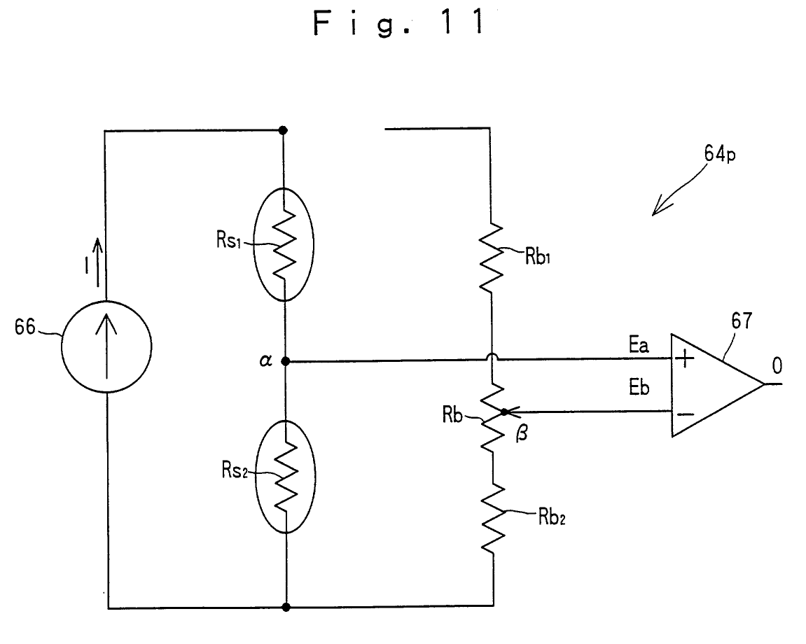

### DETAILED DESCRIPTION OF THE PREFERRED EMBODIMENTS

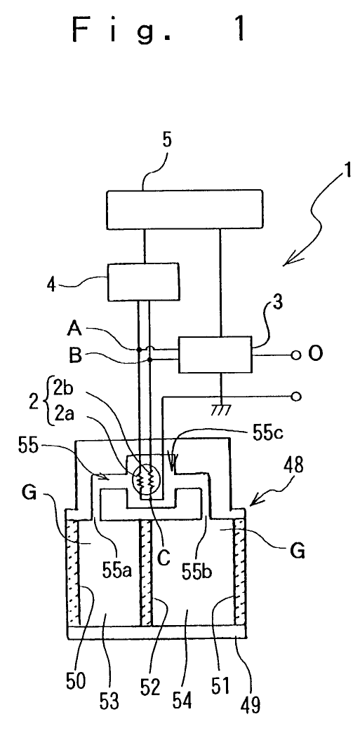

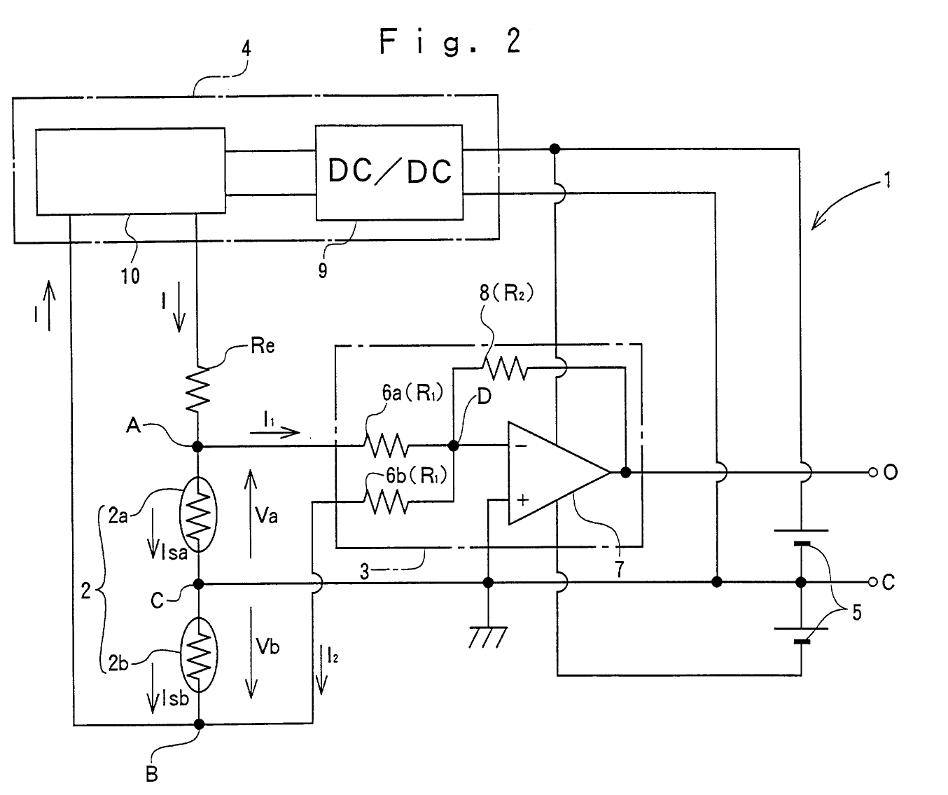

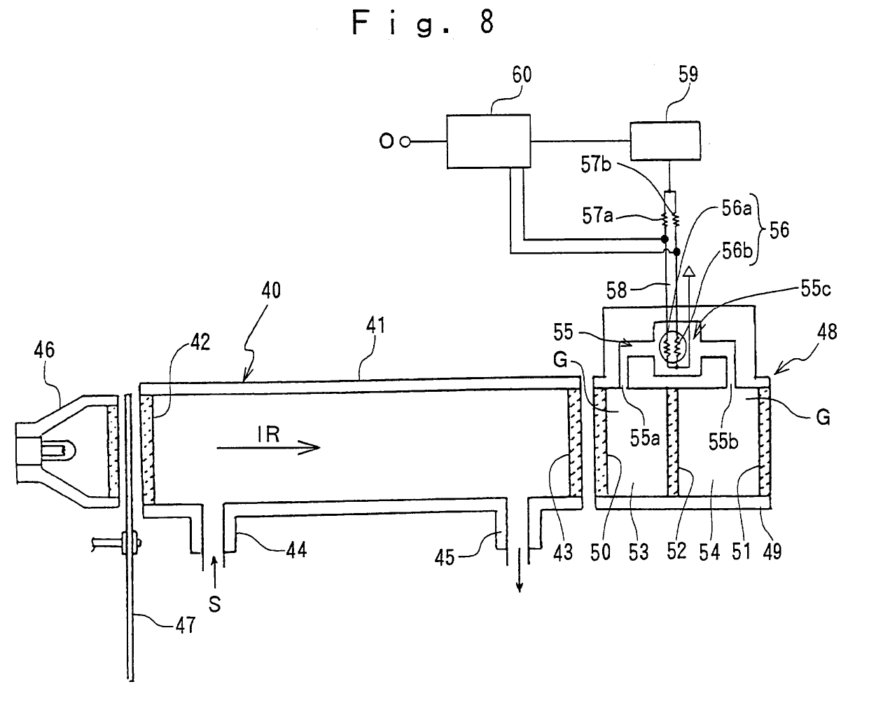

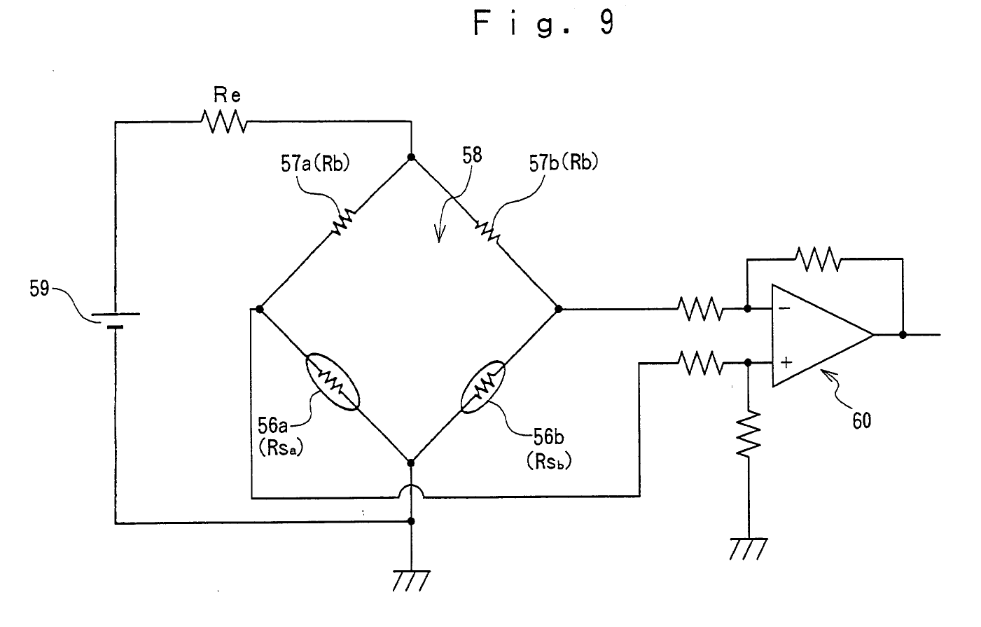

FIGS. 1 and 2 are views showing a first embodiment of the present invention. FIG. 1 is a view showing the structure of the portion of the detector of the infrared gas analyzer which executes a circuit 1 for detecting a minute change in resistance of the present invention, and FIG. 2 is a view detailing only the circuit structure. In FIG. 1 the same components as those in FIGS. 8, 9 are referred to with the same reference symbols, so that their detailed description will be omitted.

FIGS. 1 and 2 include a pair of resistance sensors 2a, 2b arranged upstream and downstream, respectively, to the flow of the gas G which is an example of a fluid; one end A and the other end B of the pair resistance sensors 2 (2a, 2b); a connection point C of the resistance sensors 2a, 2b; an amplifying circuit 3 which adds the voltage developed at A to the voltage developed at B for amplification with reference to the potential at the connection point C; a current supply 4 which supplies the resistance sensors 2a,2b with a predetermined constant current under the condition of being isolated from the amplifying circuit 3; and a DC power supply 5 which supplies these electric circuits 3, 4 with electric power.

The resistance sensors 2a, 2b are heat ray elements as an example of resistances, which have the same electric properties and evolve heat with a flowing a current, with the resistance values Rsa, Rsa having a predetermined relation to the heat. Since the resistance sensors 2a, 2b are directly exposed to the sealed gas G, they are made from a corrosion-resistant metal with a large temperature coefficient such as platinum or nickel. The connection point C is grounded to stabilize its potential.

The amplifying circuit 3 is an adding circuit composed of two resistances 6a, 6b which have the same electric properties and a resistance value R₁ far larger than the resistance values Rsa, Rsb of the resistance sensors 2a, 2b, and which are connected in series so as to be linked between one end A and the other end B of the resistance sensors 2; a calculation amplifier 7 which enters the connection point D of the resistances 6a, 6b to the reversal input terminal; and a resistance 8 which performs negative feedback of the output of the calculation amplifier 7 to the reversal input terminal.

Since the voltage Va of one end A with regard to the connection point C of the resistance sensors 2a, 2b and the voltage Vb of the other end B are opposite in polarity to each other, the subtraction of the voltage drop Va−Vb caused by the resistance sensors 2a, 2b can be calculated by making the adding circuit 3 add both voltages Va and Vb. The calculation amplifier 7 used in the adding circuit 3 can be any type as long as it is of high precision, and its non-reversal input terminal is grounded to improve the stability of the output against external disorder.

The current supply 4, which is a converter for receiving electric power from the power supply 5 of the amplifying circuit 3 and outputting a predetermined constant current under the state of being isolated from the power supply 5, can be composed of a DC-DC converter 9 of an input/output isolation type and a constant current producing circuit 10 which generating a predetermined constant current I.

In the circuit 1 for detecting a minute change in resistance of the present invention, the constant current I is supplied from the current supply 4 to the resistance sensors 2a, 2b under the state of being isolated from the power supply 5, thereby securing the current I to return to the current supply 4 without passing through another loop even when the connection point C is grounded.

In this embodiment, the resistances 6a, 6b are connected to one end A and the other end B of the resistance sensors 2a, 2b, so that the currents Isa, Isb flowing to the resistance sensors 2a, 2b and the currents I₁, I₂ divided by the resistances 6a, 6b are expressed to be strict in the following (3)-(6).

$$\begin{matrix}I s a = \frac{{R}_{1} \times I}{R s a + {R}_{1}} & formula ( 3 ) \\ I s b = \frac{{R}_{1} \times I}{R s a + {R}_{1}} & formula ( 4 ) \\ {I}_{1} = \frac{R s a \times I}{R s a + {R}_{1}} & formula ( 5 ) \\ {I}_{2} = \frac{R s b \times I}{R s a + {R}_{1}} & formula ( 6 )\end{matrix}$$

However, the resistance R₁ of the resistances 6a, 6b can be made far larger than the resistance values Rsa, Rsb of the resistance sensors 2a, 2b so as to reduce its influence to an ignorable level. For example, making the resistance value R₁ at least 1,000 times larger than the resistance values Rsa, Rsb can reduce the currents I₁, I₂ divided into the resistances 6a, 6b to about one thousands of the whole current I. As the result, the influence can be ignored, considering that Isa, Isb=I.

The power W₀ (which relates to heating value) to be applied on each of the resistance sensors 2a, 2b is expressed in the formula (7). Since the heating value is in proportion to the square of the current Is (Isa or Isb) flowing to the resistance value Rs (Rsa or R6b) of one of the resistance sensors 2a, 2b, the influence of the resistance values Rsa, Rsb on heat generation can be as small as to be ignorable by making the resistance value R₁ far larger than the resistance values Rsa, Rsb.

W₀=Is²×Rs formula (7)

In other words, only by making the resistance value RI of the resistances 6a, 6b sufficiently large, almost the entire amount of the constant current I can flow to both resistance sensors 2a, 2b, regardless of the size of the resistance values Rsa, Rsb of the resistance sensors 2a, 2b, which hardly causes an interference between the resistance sensors 2 due to changes in the resistance values Rsa, Rsb. In addition, even if there is a resistance Re, which becomes a cause of error, such as contact resistance or wire resistance on the circuit for supplying a current to the resistance sensors 2a, 2b, this never has a detrimental effect on the measured value.

In the structure of the circuit 1 for detecting a minute change in resistance shown in the present invention, the resistances 6a, 6b are not formed on the circuit for supplying power for the resistance sensors 2a, 2b to generate heat. Therefore, there is no need to flow a large amount of current to the resistances 6a, 6b; it is rather desirable to minimize the current flowing thereto. For this reason, the resistance value R₁ of the resistances 6a, 6b is made far larger than the resistance sensors Rsa, Rsb, thereby minimizing the current flowing to the resistances 6a, 6b.

As the current flows less to the resistances 6a, 6b, the heat generation from the resistances 6a, 6b can be decreased more, which contributes to energy saving and leads to stable operations of the circuit. In other words, the resistances 6a, 6b do not have to be stable or precise for self heat generation as in the conventional bias resistance Rb, which makes it possible to form a high precision circuit for detecting a minute change in resistance by using less expensive components.

Here, assume that the resistance 8 has a resistance value R₂, the voltage E outputted as the output signal 0 becomes as shown in formula (8). Since the resistance value R₁ is made far larger than the resistance values Rsa, Rsb, the currents I₁, I₂ where I₁=I₂=I can be expressed with the resistance values R₁, Rsa, Rsb as follows.

$$E = - ( {I}_{1} - {I}_{2} ) \times {R}_{2} = \frac{- ( R s a - R s b ) \times I}{{R}_{1}} \times {R}_{2} \qquad formula ( 8 )$$

Furthermore, in the formula (8), when the resistance value Rsa has a minute change in resistance value δr, the change amount δe of the voltage E outputted as the output signal 0 can be expressed in the following formula (9).

$$δ e = \frac{- δ r \times I \times {R}_{2}}{{R}_{1}} \qquad formula ( 9 )$$

Therefore, as shown in the formula (9), the sensitivity of detection can be improved by increasing the current I and by increasing the gain of the amplifying circuit 3 determined by R₂/R₁. Also in the case where the heating value is increased by increasing the current I, there is no need for adjusting the resistance value R₁ of the resistances 6a, 6b or other circuit constants. Thus, it becomes easier to cope with modifications in specification such as the resistance values of the resistance sensors 2a, 2b and the heating value.

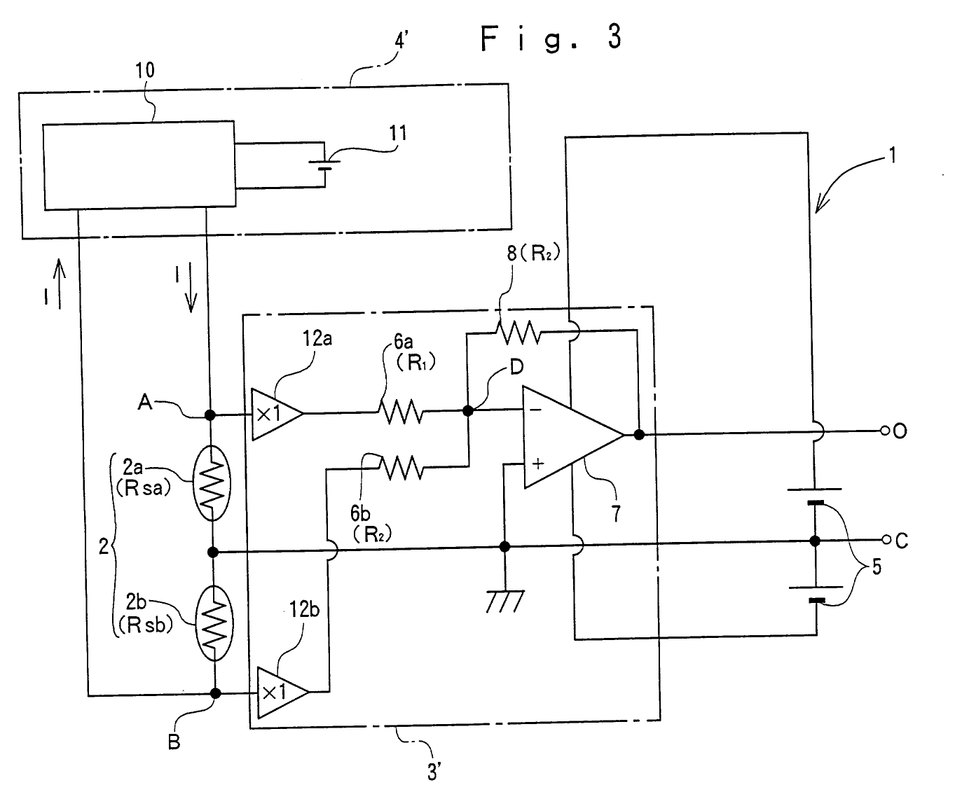

FIG. 3 is a view showing a modified example of the circuit 1 for detecting a minute change in resistance of the present invention. In FIG. 3 the same components as those in FIG. 2 are referred to with the same reference numbers, so that their detailed description and the explanation of the effects to be obtained will be omitted.

FIG. 3 shows a current supply 4′ which includes a completely independent voltage supply 11 isolated from a power supply 5, and an amplifying circuit 3′ which includes two amplifiers 12a, 12b with an amplitude of 1 for monitoring the voltages at one end A and the other end B of the resistance sensors 2.

Since the voltage supply 11′ is completely independent from the power supply 5, the constant current I, which is outputted from the constant current producing circuit 10 for converting this power into stable current and outputting it, is designed to return after passing through the resistance sensors 2a, 2b.

Since the input impedance of the amplifiers 12a, 12b is extremely high, selecting amplifiers of low bias current makes it possible to prevent diversion or merge in the one end A and the other end B because of the provision of the amplifiers 12a, 12b. In short, the two resistance sensors 2a, 2b are fed with basically the entire amount of the constant current I outputted from the current supply 4′, which enables a minute change in resistance to be detected by a method similar to the fundamental principle of measuring resistance, thereby performing a stable measurement.

As described above, the use of tie circuit for detecting a minute change in resistance of the present invention makes it possible to precisely detect minute changes in the resistance values of the sensors by the method similar to the principle of measuring resistance value. This contributes to energy saving and also enables an extremely stable detection of a minute change in resistance.

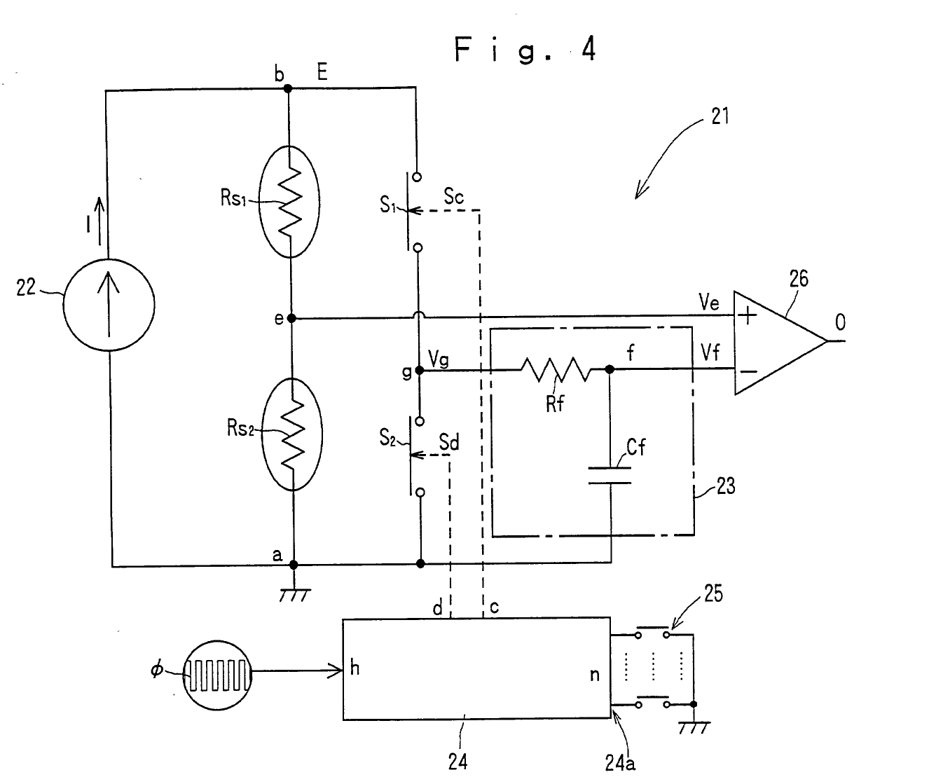

FIG. 4 is a view showing the first embodiment of the present invention, and illustrates the structure of the circuit 21 for detecting a minute change in resistance or an improvement of the circuit 64 for detecting a minute change in resistance which measures the minute change in resistance of the resistance sensors Rs₁, Rs₂ connected in series and coiled at two adjacent sites on the tube 63 composing the flow passage 63a inside the flow sensor 61 shown in FIG. 4.

In FIG. 4, a power supply 22 supplies a stable predetermined DC power to both ends of the resistance sensors Rs₁, Rs₂; a smoothing circuit 23 equalizes the entered voltage Vg and outputs it as a voltage Vf; switch elements S₁, S₂ alternately supply the smoothing circuit 23 with the voltages 0, E of both ends a, b of the resistance sensors Rs₁, Rs₂ by a switching operation; a pulse width modulation circuit 24 composed of a counter circuit supplies switching signals (pulse signals) from points c, d to the switch elements S₁, S₂; a setting switch 25 outputs the set value of pulse width to the input unit 24a of the pulse width modulation circuit 24; and an amplifier (detecting unit) 26 amplifies the difference between the voltage Ve of the connection point e of the resistance sensors Rs₁, Rs₂ and the voltage Vf of the output unit f of the smoothing circuit 23, thereby detecting the minute change of the resistance sensors Rs₁, Rs₂ and outputting the signal 0.

The power supply unit 22 can be a DC current supply for feeding the current I of predetermined magnitude to the resistance sensors Rs₁, Rs₂, which allows the resistance sensors Rs₁, Rs₂ to generate nearly fixed amounts of heat.

The smoothing circuit 23 is composed of a resistance Rf and a capacitor Cf, which is a stable film capacitor in this embodiment. In this embodiment, the constant Rf and Cf are so determined that the time constant determined by the resistance Rf and the capacitor Cf becomes longer than the time period (in the present embodiment, 0.1 second when it is 10 Hz) of voltage fluctuations of the input unit g determined by the switching frequency of the switch elements S₁, S₂. Since the time constant causes ripples in the output signal 0 when it is too short, and deteriorates traceability when it is too long, it must be set at an appropriate value. The resistance Rf is made far larger in magnitude than the resistance sensors Rs₁, Rs₂.

Although the switch elements S₁, S₂ are composed of FETs in this embodiment, the type of the switching means is not limited and they are illustrated as mere switches in FIG. 4. In other words, besides FETS, the switch elements S₁, S₂ can be bipolar transistors, analog switches, or semiconductor relays. The switching means employed as the switch elements S₁, S₂ should not cause the resistance values to change at on-off operations with time.

The pulse width modulation circuit 24 receives a pulse of, e.g., 10 MHz as an input clock ø from an input unit h, and divides this. The setting switch 25 in this embodiment is a dip switch, which can set a value of 20 digits in binary notation (0 to 10485273 in a decimal system). Also, the setting switch 25 can be a switch of another type such as a rotary encoder. The pulse width modulation circuit 24 receives a digital value n set by the setting switch 25 from the Input unit 24a, and outputs a pulse signal to turn the switch elements S₁, S₂ on alternately at the pulse share according to the value n.

Thus, the switch elements S₁, S₂, the pulse width modulation circuit 24 and the smoothing circuit 23 in the present embodiment are combined to form an intermediate voltage developing circuit which digitally divides the voltage E applied on both ends of the two resistance sensors Rs₁, Rs₂ by switching operations of the switch elements S₁, S₂.

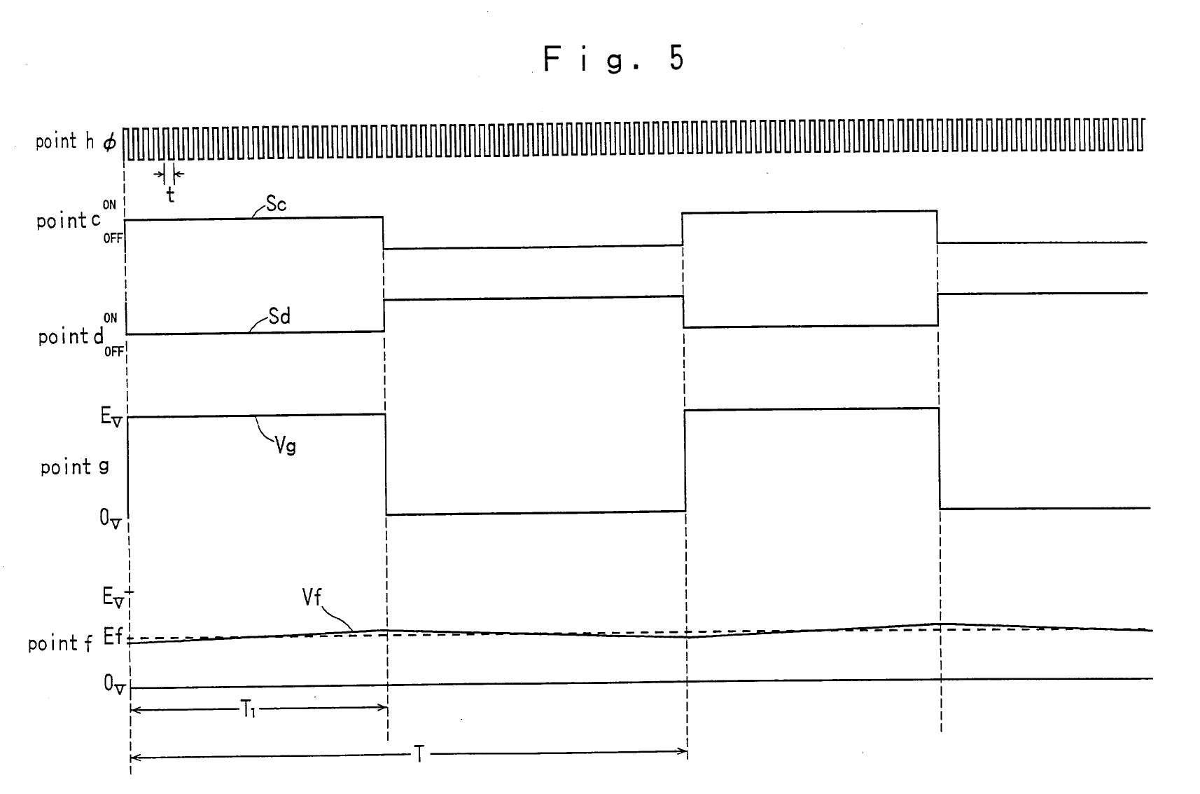

FIG. 5 is a view showing the relation between signals in each unit in the circuit 21 for detecting a minute change in resistance of the present embodiment. In FIG. 5 the clock signal ø to be entered to the input unit h of the pulse width modulation circuit 24 is a pulse signal of 10 MHz in this embodiment, and pulse signals Sc, Sd are divided by the pulse modulation circuit 24 to, e.g. 10 Hz so as to adjust the pulse share to the value set by the setting switch 25. The clock ø shown in FIG. 5 fluctuates faster in reality; however, it is simplified for illustration.

The voltage Vg at the point g shown in FIG. 4 is supplied by switching the switch elements S₁, S₂, and the voltage Vf at the point f is smoothed by the smoothing circuit 23. T is the time period of the pulse signals Se, Sd, and T₁, is the time period where the switch element S₁is on. The setting of the pulse width by the setting switch 25 is the determination of the length of the time T₁.

Assume that the average voltage of the voltage Vf at point f is Ef, the average voltage Ef and the voltage E applied on the two resistance sensors Rs₁, Rs₂ has the relation shown in formula (10) below.

Ef=(T₁/T)×E formula (10)

Assume that one time period of the clock ø is t, the times T, T₁, can be expressed in the following formulas (11), (12).

T₁=n×t formula (11)

T=m×t formula(12)

Note that m indicates a multiple which divides the clock ø , n is smaller than m and determined by the setting switch 25. When the resistance sensors Rs₁, Rs₂ have almost the same magnitude, n is about ½ m.

Since the clock ø is 10 MHz in this embodiment, the time t taken for one period is 100 ns, and when the pulse width modulation circuit 24 divides the clock ø to, e.g., 1/1,000,000, the value of m is one million. At this moment, the period T of the pulse signals Sc, Sd has a length of 0.1 second.

As the value m is larger, the pulse signals Sc, Sd generated by the pulse width modulation circuit 24 become more precise; however, making the value m too large causes the period T of the pulse signals Sc, Sd to become long, which demands extension of the time constant of the smoothing circuit 23. As a result, the circuit 21 for detecting a minute change in resistance has a slower response speed, thereby demanding more time for the later-described adjustment and deteriorating the operability. On the contrary, when the value m is too small, the pulse signals Sc, Sd generated in the pulse width modulation circuit 24 become less precise, thereby setting limitations to the precision of the circuit 21 for detecting a minute change in resistance as a whole. Therefore, this value must be set properly.

When the value of m is set at one million as in this embodiment, it is necessary that the pulse width modulation circuit 4 has a 20-bit internal binary counter (which can count from 0 to 1048573 in a decimal system) as an internal counter for counting the clock ø in order to set a value up to one million.

In other words, inside the pulse width modulation circuit 24, the value of the internal counter for counting the clock ø is compared with the value n determined by the setting switch 25, and when the value of the internal counter is smaller than the value n, the pulse width modulation circuit 24 outputs the active level as the pulse signal Sc, and the inactive level as the pulse signal Sd. As soon as the value of the internal counter becomes larger than the value n, the inactive level is outputted a the pulse signal Sc, and the active level as the pulse signal Sd. Thus, the pulse share of the pulse signals Sc, Sd become n/m and (m−n)/m, respectively.

Then, the voltage Ef divided by the intermediate voltage developing circuit 24, S₁, and S₂ becomes (n/m)E.

Since the clock ø is divided by using the 20-bit internal counter in this embodiment, the resolution of the pulse signals Sc, Sd is ½²⁰ (about 1/1,000,000), and the resolution capable of being controlled when the bit number of the internal counter is set at 16 bits is ½¹⁰ (about 1/65,000).

This embodiment details the operations of the pulse width modulation circuit 24, and indicates that the circuit 24 can be formed of a simple counter circuit; however, the present invention does not restrict the circuit to this type. In other words, a general purpose PWM control circuit can be used as the pulse width modulation circuit 24 of the present invention. In this case, too, a general-purpose IC can be used in the pulse width modulation circuit 24, thereby preventing a large increase in production cost.

The present embodiment shows an example of the pulse signals Sc, Sd in reverse operation; however, it is possible to make the voltage Vg at point g fluctuate in a manner similar to the sine wave by providing the time period for both pulse signals Sc, Sd to become inactive. Such generation of the pulse signals Sc, Sd can be done easily by making use of the PWM control circuit.

The smoothing circuit 23 in the present embodiment is a combination of the resistance Rf and the capacitor Cf; however, the present invention is not restricted to this, and the circuit can be composed of coil or other elements and is not limited to a low pass filter. For example, a notch filter such as a twin T filter or a band eliminate filter can be used. In addition, the circuit 23 does not need to use a passive filter, and can be an active filter circuit using a calculation amplifier or a filter with DSP.

In any case, the magnitude (the average value) of the voltage Vf smoothed by the smoothing circuit 23 is not affected by the circuit constant of each of the elements Rf, Cf, and even if the circuit constant of these elements Rf, Cf changes with time, it does not affect the output signal 0 because the magnitude of the average voltage Ef is fixed. In short, even if inexpensive elements with insufficient long-term stability are used as the elements Rf, Cf, it is possible to continue stable detection of a minute change in resistance without performing calibration for a long time period.

Above all, the flow meter used for a mass flow controller or the like must have long-term stability because it is not subjected to a periodic calibration, and also must be cost effective. Therefore, in the circuit structure not conducting a periodic correction such as a flow meter in particular, it is desirable to use a circuit for detecting a minute change in resistance like the circuit 21 for detecting a minute change in resistance of the present invention, which can be formed at low cost and needs no calibration.

In the present embodiment, it goes without saying that each exemplified constant is one example to make the present invention more easily understandable, and the present invention is not restricted to them. This holds true in each following case.

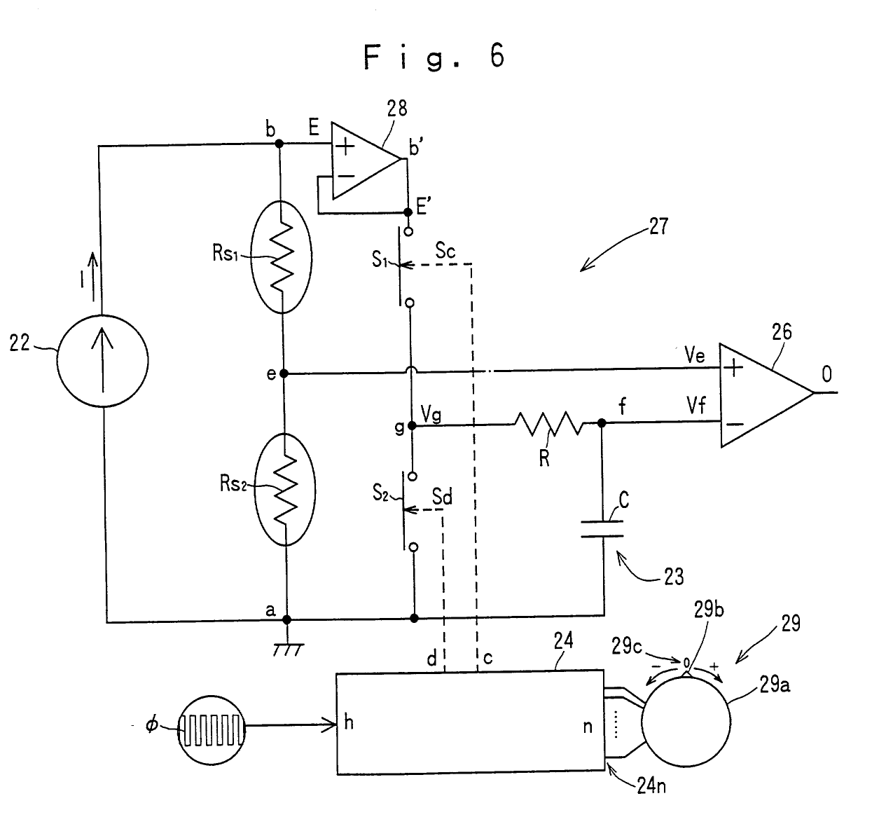

FIG. 6 is a view showing the structure of the circuit 27 for detecting a minute change in resistance as a modified example of the circuit 21 for detecting a minute change in resistance. In FIG. 6 the same components as those in FIGS. 4, 5 are referred to with the same reference numbers, so that their detailed description will be omitted.

The view includes a calculation amplifier (amplifier) 28 which is disposed between the switch element S₁ and the resistance sensor Rs₁, and a rotary encoder 29 which is a modified example of the setting switch 25.

The calculation amplifier 28 is a non-reversal amplifying circuit which makes the output point b′ negative feedback so as to compose a voltage follower providing the output voltage E′ the same as the voltage E of the point b and making the current to be divided at the point b (input side) nearly zero and making the output impedance at the point b′ on the output side nearly zero. As a result, at the point b from which the current I is fed to the resistance sensor Rs₁, fluctuations in the current I flowing to the resistance sensor Rs₁ can be actually eliminated (minimized), thereby preventing current flow to the switch element S₁ side at the on-off operations of the switch element S₁ from affecting the properties. Thus, more precision can be achieved.

The constant of the resistance Rf and the capacitor Cf composing the smoothing circuit 23 can be selected freely, thereby improving the flexibility of the circuit design. For example, it is possible to set the resistance Rf as small as the bias current of the amplifier 26 is unnoticeable so as to increase the value of the capacitor Cf, without taking the influence on the resistance sensors Rs₁, Rs₂ side into consideration. In addition, the smoothing circuit 23 can be modified variously.

The rotary encoder 29 output a digital set value n according to the angle of the rotation of the knob 29a; which has a mark 29b. The mark 29b corresponds to a display 29c indicating the reference value (500,000, for example) of the set value n as 0, and can adjust the equilibrium of the circuit having the bridge function of the circuit 27 for detecting a minute change in resistance.

Therefore, the operator can adjust the equilibrium of the circuit 27 for detecting a minute change in resistance only by turning the knob 29a, thereby determining the set value n as easily as turning a valuable resistance. Since the rotary encoder 29 sets a digital set value n, the set value n does not change whether the operator is touching the knob 29a or not, thereby facilitating the adjusting operations.

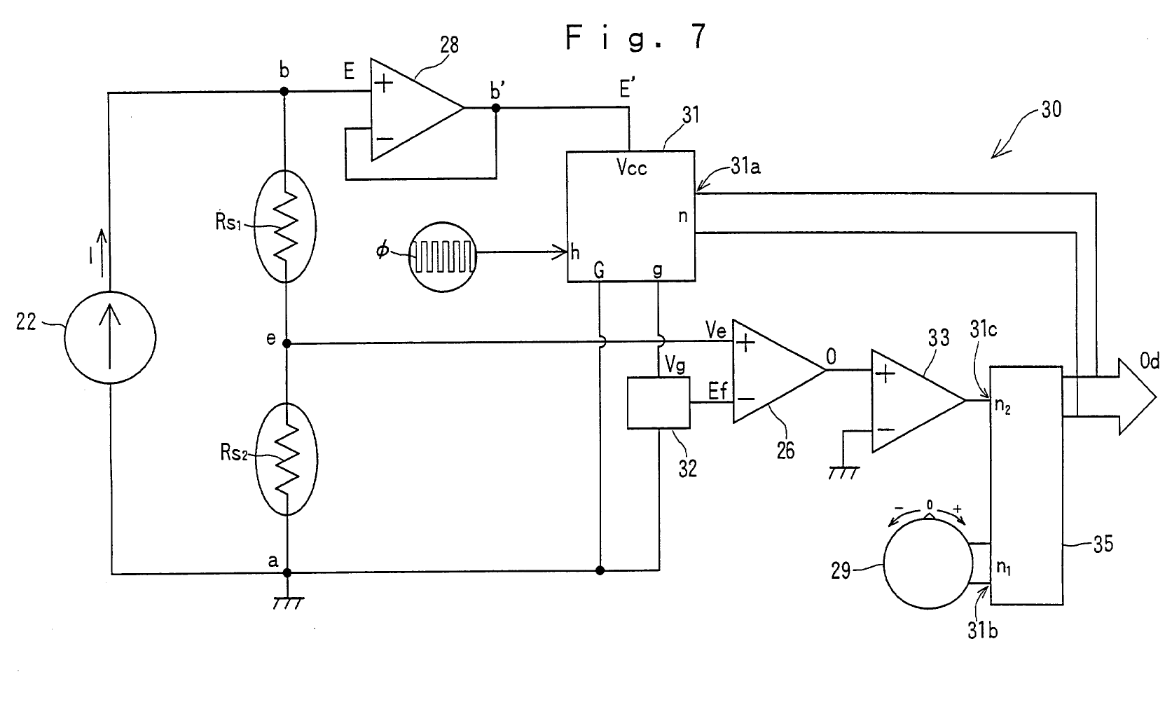

FIG. 7 is a view showing the structure of the circuit 30 for detecting a minute change in resistance as another modified example of the circuits 21, 27 for detecting a minute change in resistance. In FIG. 7 the same components as those in FIGS. 4 to 6 are referred to with the same reference numbers, so that their detailed description will be omitted.

In FIG. 7, switching circuit 31 is composed of a C-MOS integrated circuit; a smoothing circuit 32 smoothes the switching voltage Vg outputted from the switching circuit 31; a comparator 33 compares the output signal obtained through comparison by the calculation amplifier 26 with a zero voltage; and a control unit 35 receives the output of the comparator 33 as a digital value n₂, and also receives the set value n₁ of the rotary encoder 29 so as to monitor the output of the comparator 33, thereby outputting the digital signal 0d for making the output 0 zero to the input unit 31a of the switching circuit 31.

The switching circuit 31 is a programmable logic (PLD, CPLD, FPLD, or the like) that operates by receiving the output E′ of the calculation amplifier 28 to the power supply Vcc which composes an integrated circuit including the switch elements S₁, S₂ and the pulse width modulation circuit 24 shown in FIGS. 4, 5.

In other words, the switch elements S₁, S₂ in the present embodiment are FETs composing the output point g of the switching circuit 31, and the voltage E′ is entered to the power supply Vcc. As the result, the high level voltage of the switching circuit 31 becomes E′ and the low level voltage becomes 0, which makes the output signal at the output point g form the same voltage waveform as the one expressed by the symbol Vg in FIG. 5.

The smoothing circuit 32 is a low pass filter formed by an active filter using, e.g., a calculation amplifier. The detailed structure of the smoothing circuit 32 can be various in types, so that its illustration is omitted. Making the smoothing circuit 32 an active filter can easily reduce ripples caused on the output voltage Ef, thereby stabilizing the output signal 0 of the amplifier 26. However, the smoothing circuit 32 can be composed of a passive filter, or can be a filter with DSP.

Thus, the switching circuit 31 and the smoothing circuit 32 are combined to compose an intermediate voltage developing circuit.

The control unit 35 receives output of the comparator 33 as a digital value n₂ and the set value n₁, of rotary encoder 29, thereby functioning as an AD converter of a so-called sequential comparison system which integrates the output of the comparator 33, and outputs the output signal 0d to the input unit 31a of the switching circuit 31 while monitoring the output of the comparator 33 so as to make the output O zero.

In other words, the calculation amplifier 33 and the control unit 35 function as a digital signal generation circuit which outputs a set value n of pulse width for adjusting the output voltage Vg of the intermediate voltage developing circuit 31 to become equal to the voltage of the connection point of the resistance sensors. The set value n generated by the digital signal generation circuits 33, 35 can be used as it is as the digital output signal Od.

In the present embodiment to make the explanation more easily understandable, the control unit 35 which receives the digital value n₂ and the set value n₁ and outputs the proper set value n is separated from the intermediate voltage developing circuit 31; however, the control unit 35 can be integrated into the intermediate voltage developing circuit 31. In this case, the intermediate voltage developing circuit 31 is provided with an input unit 31b which receives the set value n₁ for equilibrium adjustment of the circuit having the bridge function in the state of not flowing a fluid in the form of a digital signal, and an input unit 31c which receives the digital value n₂ varying in the state of flowing the fluid.

In the case where the host computer is connected in place of the rotary encode 29, the host computer can adjust the equilibrium of the circuit 30 for detecting a minute change in resistance. Consequently, for example, the host computer can adjust and output the set value n, so adjusted to make the output signal Od zero under the conditions that the flow of the fluid is suspended, thereby conducting the zero adjustment of the circuit 30 for detecting a minute change in resistance used in the flow meter after installment at a desired point.

In addition, integrating the intermediate voltage developing circuit 31 as in the present embodiment can reduce the number of components to be used, thereby saving energy and reducing the production cost. It goes without saying that more energy saving can be achieved by integrating a circuit including analog elements, such as the smoothing circuit 32 or the calculation amplifiers 26, 33.

When the output signal Od is digital as in the present embodiment, there is the advantage that the following signal processing can be easily done by a digital circuit and that there is no need for providing an AD converter.

In each case mentioned above, the power supply unit 22 of the resistance sensors Rs₁, Rs₂ is shown as constant current supply. However, it goes without saying that the present invention does not restrict the structure of the power supply unit 22 to a constant current supply, and it can be a voltage supply.

As described above, the use or the second and third circuits for detecting a minute change in resistance of the present invention makes it possible to improve reliability by increasing stability, to improve operability in adjusting the equilibrium of the bridge, and to reduce the cost.

What is claimed is:

1. A circuit for detecting a minute change in resistance in a resistance sensor where a change in resistance value is formed into a detecting signal comprising:
two resistance sensors which have the same electric properties and are connected in series;
an amplifying circuit which adds the voltage generated between a connection point of the resistance sensors and one end thereof to the voltage generated between the connection point and the other end thereof for amplification; and
a current supply unit which feeds a predetermined constant current to the two resistance sensors in a state of being electrically isolated from the amplifying circuit.

2. The circuit for detecting a minute change in resistance according to claim 1, further comprising that the amplifying circuit is an adding circuit which includes: two resistances which have the same electric properties and resistance values much larger than the resistance sensors and which are connected in series between one end and the other end of the resistance sensors; and a calculation amplifier with a reversal input terminal connected to the connection point of the two resistances and which performs negative feedback of the output.

3. The circuit for detecting a minute change in resistance according to claim 1, and further comprising that the amplifying circuit is an adding circuit which includes:
two amplifiers having an amplitude of 1 arranged respectively at one end and the other end of the resistance sensors; two resistances having the same electric properties and connected in series so as to connect the outputs of both amplifiers; and a calculation amplifier with a reversal input terminal connected to the connection point of the resistances and which performs negative feedback of the output.

4. The circuit for detecting a minute change in resistance according to claim 1 wherein the current supply is a converter which obtains power from the power supply of the amplifying circuit, and outputs a predetermined constant current in a state of being insulated from the power supply of the amplifying circuit.

5. The circuit for detecting a minute change in resistance according to claim 2 wherein the current supply is a converter which obtains power from the power supply of the amplifying circuit, and outputs a predetermined constant current in a state of being insulated from the power supply of the amplifying circuit.

6. The circuit for detecting a minute change in resistance according to claim 3 wherein the current supply is a converter which obtains power from the power supply of the amplifying circuit, and outputs a predetermined constant current in a state of being insulated from the power supply of the amplifying circuit.

7. A circuit for detecting a minute change in resistance in a resistance sensor where a change in resistance value is formed into a detecting signal characterized by being comprised of:
a power supply unit which supplies DC current;
two resistance sensors connected in series, both ends thereof being connected with the power supply unit;
an intermediate voltage developing circuit, which digitally divides the voltage applied on both ends of the two resistance sensors by a switching operation with the use of switch elements; and
a detecting unit which detects minute changes in the resistance sensors by comparing the output voltage of the intermediate voltage developing circuit with the voltage at the connection point of the resistance sensors.

8. The circuit for detecting a minute change in resistance according to claim 7, and further comprising that the intermediate voltage developing circuit has a pulse width modulation circuit which perform the switching operations.

9. The circuit for detecting a minute change in resistance according to claim 8 wherein the pulse width modulation circuit includes an input unit which receives a set of pulse width in the form of a digital signal, and a setting switch which outputs to the input unit a set value of pulse width adjusted according to the resistance values of the resistance sensors.

10. The circuit for detecting a minute change in resistance according to claim 9 wherein the pulse width modulation circuit includes an input unit which receives the set value of pulse width in the form of a digital signal, and the detecting unit includes a digital signal generation circuit which outputs to the input unit the set value of pulse width to equalize the output voltage of the intermediate voltage developing circuit to the voltage of the connection point of the resistance sensors.

11. The circuit for detecting a minute change in resistance according to claim 7 wherein the circuit for detecting a minute change in resistance further comprises an amplifier disposed between the switch elements and the resistance sensors so as to minimize changes in the current flowing to the resistance sensors.

12. A circuit for detecting a minute change in resistance in a resistance sensor where a change in resistance value is formed into a detecting signal characterized by being comprised of:
two resistance sensors connected in series and coiled at two adjacent sites on a tube providing a flow passage of a fluid;
a power supply unit which supplies a predetermined DC power to both ends of the resistance sensors;
a smoothing circuit which equalizes the entered voltages and outputs them;
two switch elements which supply the smoothing circuit with the voltages at both ends of the resistance sensors alternately by a switching operation;
a pulse width modulation circuit which supplies switching signals to the switch elements; and
a detecting unit which detects minute changes in the resistance sensors by comparing the voltage at the connection point of the resistance sensors with the output voltage of the smoothing circuit.

13. The circuit for detecting a minute change in resistance according to claim 12 wherein the pulse width modulation circuit includes an input unit which receives a set value of pulse width in the form of a digital signal, and a setting switch which outputs to the input unit a set value of pulse width adjusted according to the resistance values of the resistance sensors.

14. The circuit for detecting a minute change in resistance according to claim 13 wherein the pulse width modulation circuit includes an input unit which receives the set value of pulse width in the form of a digital signal, and the detecting unit includes a digital signal generation circuit which outputs to the input the set value of pulse width to equalize the output voltage of the intermediate voltage developing circuit to the voltage of the connection point of the resistance sensors.

15. The circuit for detecting a minute change in resistance according to claim 14 wherein the circuit for detecting a minute change in resistance further comprises an amplifier disposed between the switch elements and the resistance sensors so as to minimize changes in the current flowing to the resistance sensors.

16. A circuit for detecting a minute change in resistance in a resistance sensor where a change in resistance value is formed into a detecting signal characterized by being comprised of:
a power supply unit which supplies DC power;
two resistance sensors connected in series, both ends thereof being connected to the power supply unit;
an intermediate voltage developing circuit which digitally divides the voltages applied on both ends of the two resistance sensors through switching operations with the use of switch elements; and
a detecting unit which detects minute changes in the resistance sensors by comparing the output voltage of the intermediate voltage developing circuit with the voltage at the connection point of the resistance sensors, thereby adding the voltage developed between the connection point of the two resistance sensors and one end thereof to the voltage developed between the connection point and the other end thereof.

17. The circuit for detecting a minute change in resistance according to claim 16 and further comprising that the intermediate voltage developing circuit has a pulse width modulation circuit which performs switching operations.

18. The circuit for detecting a minute change in resistance according to claim 17 wherein the pulse width modification circuit includes an input unit which receives the set value of pulse width in the form of a digital signal, and a setting switch which outputs to the input unit a set value of pulse width adjusted according to the resistance values of the resistance sensors.

19. The circuit for detecting a minute change in resistance according to claim 17 wherein the pulse width modulation circuit includes an input unit which receives the set value of pulse width in the form of a digital signal, and the detecting unit includes a digital signal generation circuit which outputs to the input unit the set value of pulse width to equalize the output voltage of the intermediate voltage developing circuit to the voltage of the connection point of the resistance sensors.

20. The circuit for detecting a minute change in resistance according to claim 17 wherein the circuit for detecting a minute change in resistance further comprises an amplifier disposed between the switch elements and the resistance sensors so as to minimize changes in the current flowing to the resistance sensors.

21. A circuit for detecting a minute change in resistance in a resistance sensor where a change in resistance value is formed into a detecting signal characterized by being comprised of:
two resistance sensors connected in series and coiled at two adjacent sites on a tube providing the fluid passage;
a power supply unit which supplies a predetermined DC power to both ends of these resistance sensors;
a smoothing circuit which equalizes the entered voltages and outputs them;
two switch elements which supply the smoothing circuit with the voltages at both ends of the resistance sensors alternately by a switching operation;
a pulse width modulation circuit which supplies switching signals to the switch elements; and
a detecting unit which detects minute changes in the resistance sensors by comparing the voltage at the connection point of the resistance sensors with the output voltage of the smoothing circuit, thereby adding the voltage developed between the connection point of the two resistance sensors and one end thereof to the voltage developed between the connection point and the other end thereof.

22. The circuit for detecting a minute change in resistance according to claim 21 wherein the pulse width modulation circuit includes an input unit which receives a set value of pulse width in the form of a digital signal, and a setting switch which outputs to the input unit a set value of pulse width adjusted according to the resistance values of the resistance sensors.

23. The circuit for detecting a minute change in resistance according to claim 21 wherein the pulse width modulation circuit includes an input unit which receives the set value of pulse width in the form of a digital signal, and the detecting unit includes a digital signal generation circuit which outputs to the input unit the set value of pulse width to equalize the output voltage of the intermediate voltage developing circuit to the voltage of the connection point of the resistance sensors.

24. The circuit for detecting a minute change in resistance according to claim 21 wherein the circuit for detecting a minute change in resistance further comprises an amplifier disposed between the switch elements and the resistance sensors so as to minimize changes in the current flowing to the resistance sensors.
